(19) United States
(12) Patent Application Publication
(10) Pub. No.: US 2024/0114595 A1
(43) Pub. Date: Apr. 4, 2024

(54) COOKING APPLIANCE

(71) Applicant: SAMSUNG ELECTRONICS CO., LTD., Suwon-si (KR)

(72) Inventors: Sangwon YUN, Suwon-si (KR); Jaegyeong MA, Suwon-si (KR); Chulwoo LEE, Suwon-si (KR)

(73) Assignee: SAMSUNG ELECTRONICS CO., LTD., Suwon-si (KR)

(21) Appl. No.: 18/537,173

(22) Filed: Dec. 12, 2023

Related U.S. Application Data
(63) Continuation of application No. PCT/KR2022/009197, filed on Jun. 28, 2022.

(30) Foreign Application Priority Data
Jul. 5, 2021 (KR) 10-2021-0087660
Oct. 6, 2021 (KR) 10-2021-0132658

(51) Int. Cl. H05B 1/02; H05K 5/02

(52) U.S. Cl. CPC H05B 1/0258; H05K 5/0247

(57) ABSTRACT

A cooking appliance comprise an outer housing; an inner housing disposed inside the outer housing; an electrical compartment formed in the inner housing; an electrical compartment plate arranged between the outer housing and the inner housing, and including a bracket opening on one side; and a bracket module separably coupled to the electrical compartment plate. The bracket module includes: a bracket plate configured to cover the bracket opening in response to the bracket module being coupled to the electrical compartment plate; and an electric component coupled to one side of the bracket plate, and to be located inside the electrical compartment through the bracket opening while the bracket module is coupled to the electrical compartment plate, wherein the bracket module is separated from the electrical compartment such that the electric component is configured to be separated to the outside of the electrical compartment.

### TECHNICAL FIELD

The disclosure relates to a cooking appliance. More specifically, the disclosure relates to a cooking appliance having a bracket module for facilitating service through replacement of electrical components when the electrical components fail.

### BACKGROUND ART

Cooking appliances are apparatus for heating and cooking an object to be cooked, such as food, and refer to devices that provide various functions related to cooking such as heating, defrosting, drying, and sterilizing of an object to be cooked. Examples of such cooking appliance include an oven such as a gas oven or an electric oven, a microwave heating device (hereinafter referred to as a microwave), a gas stove, an electric stove, an Over The Range (OTR) a gas grill, an electric grill, and the like.

The OTR among the cooking appliances is a microwave that combines a hood function for ventilation in a kitchen, and features minimizing the installation space while ensuring convenience and efficiency of cooking food. The OTR may be located above a cooking appliance, such as a gas oven or cooktop.

Since the OTR among the cooking appliances may be located above a cooking appliance, such as a gas oven or cooktop, there is difficulty in servicing the OTP. When replacing electrical components inside the OTR, the OTR needs to be separated from the upper side of the cooking appliance and lowered, and an outer housing needs to be separated from the OTP to replace the electrical components located inside of the outer housing. Such a process may lead to increasing service costs when replacing electrical components that require frequent replacement.

### DISCLOSURE

### Technical Problem

One aspect of the disclosure provides a cooking appliance that allows for a service of replacing electrical components located inside of an outer housing without separating the cooking appliance from the arranged position.

One aspect of the disclosure provides a cooking appliance that allows electrical components inside a housing to be easily separated from the housing or mounted to the inside of the housing.

According to an aspect of the disclosure, there is provided a cooking appliance including: an outer housing; an inner housing disposed inside the outer housing; an electrical compartment formed in the inner housing; an electrical compartment plate arranged between the outer housing and the inner housing to divide the electrical compartment, and the electrical compartment plate including a bracket opening on one side thereof; and a bracket module separably coupled to the electrical compartment plate, the bracket module including: a bracket plate configured to cover the bracket opening in response to the bracket module being coupled to the electrical compartment plate; and an electrical component coupled to one side of the bracket plate, and to be located inside of the electrical compartment through the bracket opening while the bracket module is coupled to the electrical compartment plate, wherein the bracket module is separated from the electrical compartment plate such that the electrical component is configured to be separable to an outside of the electrical compartment.

The bracket opening may have a size such that the electrical component may be separable to the outside of the electrical compartment through the bracket opening in response to the bracket module being separated from the electrical compartment plate.

The bracket plate may include an outer surface facing in a direction opposite to a direction toward the electrical compartment, and the bracket plate may include an inner side facing the electrical compartment and an outer side facing the opposite side in the outward direction, and the inner side of the bracket plate includes a cover portion corresponding to the bracket opening and a support portion formed along a circumference of the bracket opening and supported by the outer surface of the bracket plate.

The electrical component may be coupled to the cover portion of the bracket plate.

The bracket module may further include a fastening member coupled to one side of the bracket plate in a direction from an outer side to an inner side of the bracket plate.

The bracket module may further include a locking member formed to extend from an other side of the bracket plate, and configured to be inserted into the electrical compartment through the bracket opening and supported on an inner surface of the electrical compartment plate while the bracket module is coupled to the bracket plate.

The locking member may have a width smaller than a width of the bracket opening such that the bracket module is configured to be separable to the outside of the housing.

The locking member may include: a locking connection portion bent at the other side of the bracket plate in a direction in which the bracket module is coupled to the bracket opening, and extending by a height of a boundary of the bracket opening such that the bracket plate is coupled in close contact with the housing; and a locking support portion bent at an end tip of the locking connection portion and extending in a longitudinal direction of the bracket module.

The bracket module may include a reinforcing protrusion formed in a longitudinal direction of the bracket plate to reinforce the bracket plate, and the reinforcing protrusion may be formed on an outer side of the bracket plate such that the bracket plate is coupled in close contact with the inner housing.

The electrical component may include an electrical component fixing hole formed on a surface coupled to the bracket plate, the bracket plate may include a plate fixing hole formed at a position corresponding to the electrical component fixing hole, and the bracket module may include an electrical component fixing member coupled at a position corresponding to the electrical component fixing hole and the plate fixing hole on an outer side of the bracket plate to couple the electrical component to the bracket plate.

The bracket module may include a guide member located adjacent to the plate fixing hole and protruding from the inner side of the bracket plate to guide fastening of the electrical component fixing member to the plate fixing hole.

The electrical component fixing hole may be a first electrical component fixing hole, the electrical component may include a second electrical component fixing hole, formed at a side opposite the first electrical component fixing hole, on a surface coupled to the bracket plate, and the bracket module may include an electrical component fitting member at a position corresponding to the second electrical component fixing hole on the bracket plate, the electrical component fitting member protruding toward the electrical component to fix the electrical component to the bracket plate.

The electrical component fitting member may include a fitting connection portion, accommodated in the second electrical component fixing hole and a fitting support portion formed to extend in the longitudinal direction of the bracket plate from an end tip of the fitting connection portion to prevent the electrical component from being separated from the bracket plate, and a fitting accommodating portion formed to bent from an end tip of the fitting support portion and extended in a direction in which the electrical component is coupled to the bracket plate such that the electrical component may be easily coupled to the electrical component fitting member.

The outer housing may further include a housing plate separably coupled to the bracket plate to cover the electrical compartment plate, and the bracket module may be accessible in response to the housing plate being separated from the electrical compartment plate.

The housing plate may form a bottom of the cooking appliance and include an air inlet, the bracket module may be separably coupled to a lower surface of a front side of the electrical compartment plate, and a circulating air intake port may be formed on a rear side of the electrical compartment plate to intake external air through the air inlet.

According to an aspect of the disclosure, there is provided a cooking appliance located above a home appliance that heats and cooks food, the cooking appliance including: an outer housing including a bracket opening on one side thereof; an electrical compartment provided inside the housing; and a bracket module inserted into the bracket opening and separably coupled to the housing, wherein the housing includes a housing plate coupled to one side of the housing to cover the bracket module, and the bracket module includes a bracket plate configured to, in response to the bracket module being coupled to the bracket opening, cover the bracket opening, and an electrical component coupled to one side of the bracket plate and in response to the bracket module being coupled to the housing, located inside the electrical compartment.

In order for the bracket module to be separated to the outside of the housing, the bracket opening may have a bracket opening boundary that is spaced outwardly from an edge of the electrical component that is obtained as a cross section taken along a plane perpendicular to a straight line in the height direction of the electrical component.

In order to prevent the bracket plate from being inserted into an area inside of the bracket opening when the bracket module is coupled to the housing, the longitudinal length of the bracket plate may be longer than the shortest one of the straight lines obtained by connecting two points on the boundary of the bracket opening.

According to an aspect of the disclosure, there is provided a cooking appliance including: a housing including a bracket opening on one side thereof; and a bracket module separably coupled to a lower side of the housing and located to correspond with the bracket opening, wherein the bracket module includes: a bracket plate including a coupling hole on one side and a locking member on the other side; a sensor coupled to the bracket module; and a coupling member configured to couple the bracket plate and the housing, and the housing includes: a housing plate configured to cover the bracket module and separably coupled to a lower side of the housing.

The bracket opening may be formed to have a size such that the sensor may be separable to the outside of the electrical compartment through the bracket opening in response to the bracket module being separated from the housing.

### Advantageous Effects

According to the disclosure, the cooking appliance includes a bracket module that is separable from an electrical compartment plate, thereby allowing for a service of replacing electrical components without separating the cooking appliance from the arranged position.

According to the disclosure, the cooking appliance includes a bracket module provided at one side with a coupling member and at the other side with a locking member, thereby allowing the bracket module to be easily separated from the housing or mounted to the inside of the housing.

### DESCRIPTION OF DRAWINGS

FIG. 1 is a perspective view illustrating a cooking appliance according to an embodiment according to the disclosure.

FIG. 2 is a perspective view illustrating the cooking appliance shown in FIG. 1, when viewed from below.

FIG. 3 is an exploded perspective view illustrating a state in which an outer housing cover and a housing plate are separated from the cooking appliance shown in FIG. 2.

FIG. 4 is an enlarged perspective view illustrating a portion, in which a bracket module is located, of the cooking appliance shown in FIG. 3.

FIG. 5 is a cross-sectional view taken along AA′ of the bracket module coupled to the housing plate in the cooking appliance shown in FIG. 3.

FIG. 6 is an enlarged perspective view illustrating the bracket module separated from the housing plate in the cooking appliance shown in FIG. 4.

FIG. 7 is an enlarged perspective view illustrating the bracket module separated from the cooking appliance shown in FIG. 6.

FIG. 8 is an exploded perspective view illustrating a state in which components of the bracket module shown in FIG. 7 are disassembled.

FIG. 9 is a cross-sectional view taken along BB′ of the bracket module shown in FIG. 7.

FIG. 10 is a perspective view illustrating a process of the housing plate being separated from the cooking appliance of FIG. 1.

FIG. 11 is an enlarged perspective view illustrating a process of a fastening member being separated from the bracket module of the cooking appliance shown in FIG. 10.

FIG. 12 is an enlarged perspective view illustrating a process in which the bracket module of the cooking appliance shown in FIG. 11 is rotated and separated from an electrical compartment plate.

FIG. 13 is an enlarged perspective view illustrating a state in which the bracket module of the cooking appliance shown in FIG. 12 has been separated from the electrical compartment plate.

FIG. 14 is an enlarged perspective view illustrating a bracket module of a cooking appliance according to another embodiment according to the disclosure.

FIG. 15 is a perspective view illustrating a cooking appliance according to another embodiment according to the disclosure.

### MODES OF THE DISCLOSURE

Embodiments described in the specification and configurations shown in the accompanying drawings are merely exemplary examples according to the disclosure, and various modifications may replace the embodiments and the drawings according to the disclosure at the time of filing of the present application.

Further, identical symbols or numbers in the drawings according to the disclosure denote components or elements configured to perform substantially identical functions.

Further, terms used herein are only for the purpose of describing particular embodiments and are not intended to limit to the disclosure. The singular form is intended to include the plural form as well, unless the context clearly indicates otherwise. It should be further understood that the terms “include,” “including,” “have,” and/or “having” specify the presence of stated features, integers, steps, operations, elements, components, and/or groups thereof, but do not preclude the presence or addition of one or more other features, integers, steps, operations, elements, components, and/or groups thereof.

Further, it should be understood that, although the terms “first,” “second,” etc. may be used herein to describe various elements, the elements are not limited by the terms, and the terms are only used to distinguish one element from another. For example, a first element could be termed a second element, and similarly, a second element could be termed a first element without departing from the scope according to the disclosure. The term “and/or” includes combinations of one or all of a plurality of associated listed items.

Meanwhile, the terms “upper-lower direction,” lower side” and “front-rear direction” used herein are defined based on the drawings, and the shape and position of each element are not limited by the terms.

Hereinafter, preferred embodiments according to the disclosure will be described in detail.

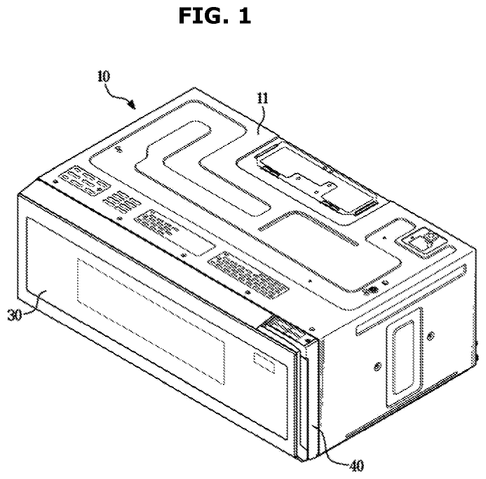

FIG. 1 is a perspective view illustrating a cooking appliance 1 according to an embodiment of the disclosure.

Referring to FIG. 1, a cooking appliance 1 may include an outer housing 10 constituting the external appearance and a door 30 coupled to the front of the outer housing 10.

The cooking appliance 1 may include a control unit coupled to the front of the outer housing 10. The front of the control unit may be covered by a door 30. More specifically, the control unit may be coupled to the outer housing 10 to be disposed between the door 30 and the outer housing 10.

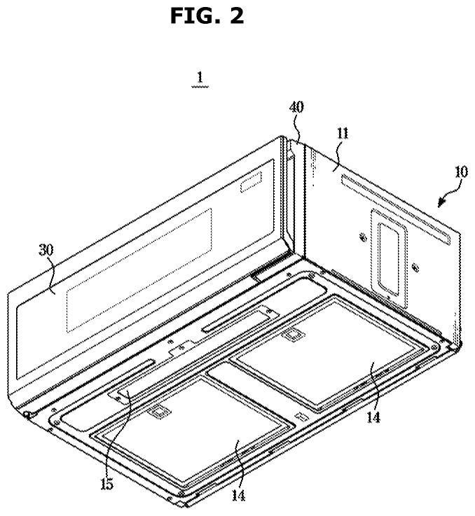

FIG. 2 is a perspective view illustrating the cooking appliance 1 shown in FIG. 1, when viewed from below.

Referring to FIG. 2, the outer housing 10 of the cooking appliance 1 may include an outer housing cover 11 including an upper surface and both side surfaces of the outer housing 10 and a housing plate 13 forming a lower surface of the outer housing 10. The housing plate 13 may be separately formed from the outer housing cover 11, but may also be integrally formed with the outer housing cover 11.

The housing plate 13 may include a circulating air intake port 14 that intakes external air.

For convenience of description, a microwave that has a separate home appliance placed on the lower side and provides a hood function to discharge steam generated from the home appliance to the outside is taken as an example. However, it is not limited thereto, and the disclosure is applicable to all types of cooking appliances.

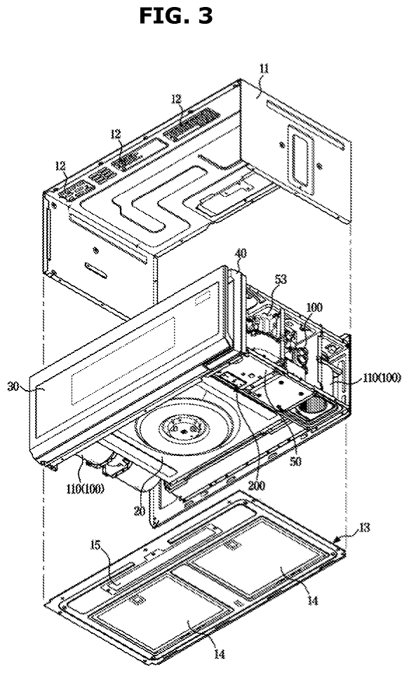

On the lower side of the cooking appliance 1 according to the disclosure, food may be separately cooked, and when the food is cooked on the lower side of the cooking appliance 1, oil vapor may be generated. In this case, since the cooking appliance 1 according to the disclosure may perform a hood function, the cooking appliance 1 may intake the oil vapor generated while cooking food to discharge the oil vapor to the outside. In this case, when a vent fan (110 in FIG. 3) located inside the outer housing 10 may be operated, the oil vapor generated from food may be intaken into the outer housing 10 through the circulating air intake port 14.

Because food is cooked on the lower side thereof, the housing plate 13, which may be located on the lower side of the cooking appliance 1 may be provided with the circulating air intake port 14.

The intaken oil vapor may flow inside the outer housing 10 and then pass through a circulating air exhaust port (12 in FIG. 3), exiting the cooking appliance 1.

The housing plate 13 may include a lighting unit 15. The lighting unit 15 may be placed in front of the circulating air intake port 14. The lighting unit 15 may be provided to emit light to the lower side of the cooking appliance 1 when a cooktop and the like are installed below the cooking appliance 1.

FIG. 3 is an exploded perspective view illustrating a state in which an outer housing cover 11 and a housing plate 13 are separated from the cooking appliance 1 shown in FIG. 2.

Referring to FIG. 3, the outer housing 10 may have the upper surface and the both side surfaces integrally formed with each other to form the outer housing cover 11. Since the outer housing cover 11 may be formed as one part, the assembly time may be shortened compared to when forming each surface with an individual plate.

The outer housing cover 11 may include the circulating air exhaust port 12 on the upper surface thereof. Since the housing plate 13 located on the lower side of the outer housing 10 may include the circulating air intake port 14, the air introduced into the cooking appliance 1 through the circulating air intake port 14 may be discharged to the outside through the circulating air exhaust port 12 located on the upper surface of the outer housing 10.

Housings 10 and 20 may include an inner housing 20 and an outer housing 10.

The inner housing 20 may be disposed inside the outer housing 10 to form a cooking chamber (not shown). A separation space (not shown) may be provided between the outer housing 10 and the inner housing 20.

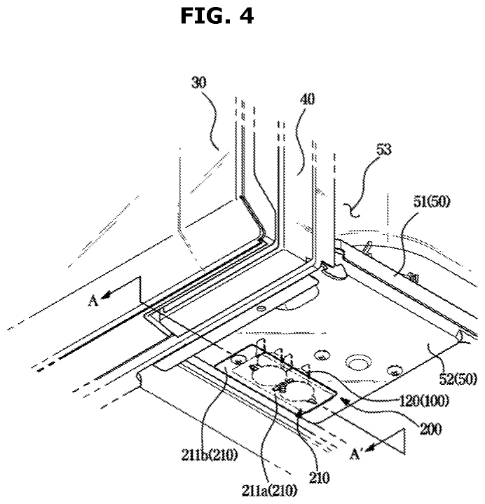

The separation space (not shown) between the outer housing 10 and the inner housing 20 may have an electrical compartment 53 in which electrical components 100 are located. An electrical compartment plate 50 may be located on the lower side of the electrical compartment 53 to partition the electrical compartment 53. In other words, the space surrounded by the electrical compartment plate 50, the inner housing 20, and the outer housing 10 may be referred to as the electrical compartment 53. The electrical compartment 53 located on the upper side of the electrical compartment plate 50 may have various electrical components 100 for driving the cooking appliance 1. The electrical components 100 may include a magnetron (not shown), a sensor (120 in FIG. 4), and the like.

The electrical compartment plate 50 may include an inner surface 51 facing the electrical compartment 53 and an outer surface 52 located on the opposite side of the inner surface 51. A bracket module 200 formed by coupling the electrical components 100 may be separably coupled to the outer surface 52 of the electrical compartment plate 50. The bracket module 200 may be separated such that the electrical components 100 may be easily separated to the outside of the cooking appliance 1, facilitating replacement of the electrical components 100. This will be described below.

In addition, the bracket module 200 may be provided on the front side lower surface of the electrical compartment plate 50. Since the bracket module 200 is provided on the front side of the electrical compartment plate 50, the electrical component 100 may be easily accessed by a person to replace the electrical component 100.

Since a process of replacing the vent fan 110 requires removing the cooking appliance 1 from the installed location and separating the outer housing 10 to perform the replacement of the vent fan 110, it is difficult to simply separate and install the vent fan 110 in the location in the cooking appliance 1 is installed. The vent fan 110 may be arranged behind the bracket module 200 because the bracket module 200 is located on the front side.

However, the arrangement is only an example, and it is not limited thereto, and the bracket module including the vent fan 110 may also be considered to be included in the disclosure.

FIG. 4 is an enlarged perspective view illustrating a portion, in which the bracket module 200 is located, of the cooking appliance 1 shown in FIG. 3.

Referring to FIG. 4, the bracket module 200 may include an electrical component 100. The electrical component 100 may include a sensor 120.

The bracket module 200 may include a bracket plate 210. The electrical component 100 may be coupled to the bracket plate 210.

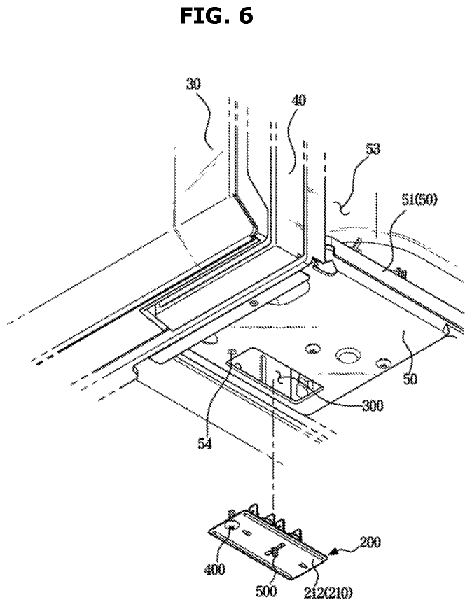

The electrical compartment plate 50 may include a bracket opening (300 in FIG. 6). The bracket module 200 may be coupled to the electrical compartment plate 50 at a position corresponding to the bracket opening (300 in FIG. 6).

The bracket plate 210 may include an inner side 211 facing the electrical compartment 53 and an outer side 212 facing away from the inner side 211. The inner side 211 of the bracket plate 210 may include a support portion 211b to be in contact with the electrical compartment plate 50 and a cover portion 211a corresponding to the bracket opening 300 while the bracket plate 210 is coupled to the electrical compartment plate 50. Since the support portion 211b of the bracket plate 210 prevents the entirety of the bracket plate 210 from be accommodated in the bracket opening 300, the bracket module 200 may be coupled to the outside of the electrical compartment 53 without entering the electrical compartment 53. Since the bracket module 200 is located outside the electrical compartment 53, when replacing the electrical component 100, the service may be easily performed by separating the bracket module 200.

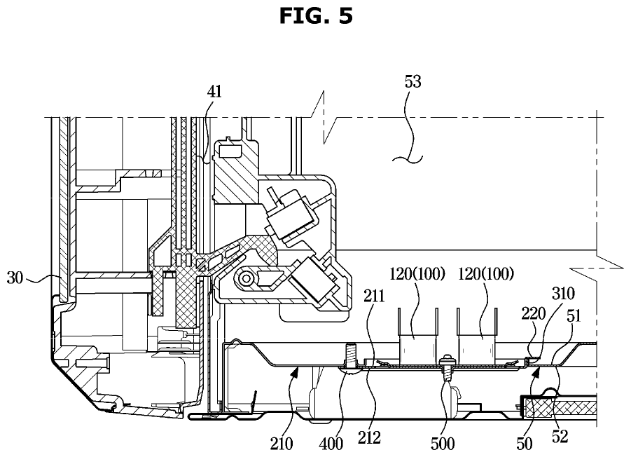

FIG. 5 is a cross-sectional view taken along AA′ of the bracket module 200 coupled to the housing plate 13 in the cooking appliance 1 shown in FIG. 3.

Referring to FIG. 5, the electrical compartment plate 50 may be coupled at one side thereof with the bracket module 200.

When replacement of an electrical component 100 is required, a control panel 40 may be separated from an outer housing 10 and the electrical component 100 may be replaced through a control panel opening 41. However, such a method has a difficulty in replacing the electrical component 100 when the electrical component 100 to be replaced is positioned away from the control panel opening 41 due to various design, such as a lower height of the cooking appliance 1, or when another electrical component 100 is located between the control panel opening 41 and the electrical component 100 to be replaced and thus it is difficult to access the electrical component 100 to be replaced.

According to the disclosure, replacement of the electrical component 100 may be easily performed by separating the electrical component 100 from the lower side of the electrical compartment 53.

The bracket module 200 may be coupled to the electrical compartment plate 50 with a fastening member 400 coupled at one side thereof and a locking member 220 located on the other side and locked with the inner surface 51 of the electrical compartment plate 50.

The inner circumference of the bracket opening (300 in FIG. 6) may have the same height as that of the inner surface 51 of the bracket plate 210 located around the bracket opening 300, but the inner circumference of the bracket opening 300 may include an inner circumference boundary portion 310 protruding inward of the electrical compartment 53 to facilitate coupling of the bracket module 200.

When the inner circumference boundary portion 310 is provided, a locking connection portion 221 of the bracket module 200 may have a height that is set to be equal to the height of the inner circumference boundary portion 310. As a result, the bracket plate 210 may be coupled in close contact with the electrical compartment plate 50.

In other words, when the bracket module 200 includes the locking member 220 that is bent from the inner side 211 of the bracket plate 210 and is extended in the direction in which the bracket module 200 is coupled to the bracket opening (300 in FIG. 6), the length to which the locking member 220 is extended with a bent may be equal to the height of the boundary of the bracket opening 300.

FIG. 6 is an enlarged perspective view illustrating the bracket module 200 separated from the housing plate 13 in the cooking appliance 1 shown in FIG. 4.

Referring to FIG. 6, the electrical compartment plate 50 may include the bracket opening 300. The bracket opening 300 may have a size that allows the electrical component 100 included in the bracket module 200 to be separated to the outside of the electrical compartment 53 through the bracket opening 300.

For example, in order that the bracket module 200 is separated to the outside of the electrical compartment 53, the boundary of the bracket opening 300 may be outwardly spaced apart from the edge of the electrical component 100 when the bracket module 200 is in a coupled state.

In other words, in order that the bracket module 200 is separated to the outside of the electrical compartment plate 50, the area of the bracket opening 300 may be larger than the area taken along a plane perpendicular to the straight line in the height direction of the electrical component 100 when the bracket module 200 is in a coupled state.

Such a structure may also be expressed using the cover portion (211a, in FIG. 4) and the support portion (211b in FIG. 5) described above. When the bracket module 200 is separated from the electrical compartment plate 50 while the electrical component 100 is coupled to the cover portion (211a in FIG. 4) of the bracket plate 210, the electrical component 100 may be easily withdraw to the outside of the electrical compartment 53 without being caught with the bracket opening 300.

Although it is required to have a structure that allows the bracket module 200 to be separated such that the electrical component 100 included in the bracket module 200 is separated and the electrical component 100 is easily replaced, it is also required to prevent the bracket module 200 from entering the electrical compartment 53 such that the bracket module 200 is easily separated from the outside.

As described above, the bracket plate 210 may include the support portion (211b in FIG. 4) that is in contact with the outer surface 52 of the electrical compartment plate 50, which prevents the bracket module 200 from entering the electrical compartment 53.

For example, in order to prevent the bracket plate 210 from being inserted into the bracket opening 300 when the bracket module 200 is coupled to the electrical compartment plate 50, the length of the bracket plate 210 in the longitudinal direction may be set to be longer than the shortest straight line obtained by connecting two points on the boundary of the bracket opening 300.

In other words, in order to prevent the bracket plate 210 from being inserted into the bracket opening 300 when the bracket module 200 is coupled to the electrical compartment plate 50, the area of the bracket plate 210 may be set to be larger than the area of the bracket opening 300.

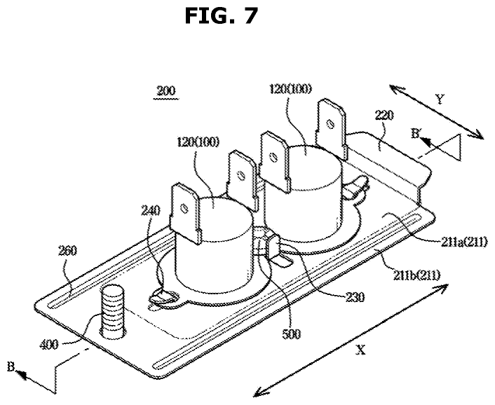

FIG. 7 is an enlarged perspective view illustrating the bracket module 200 separated from the cooking appliance 1 shown in FIG. 6.

Referring to FIG. 7, for convenience of description, the following description is made by defining the longitudinal direction X and the width direction Y of the bracket plate 210 as shown in FIG. 7.

The bracket module 200 may include the bracket plate 210. The bracket plate 210 may have a shape of a thin plate. For convenience of description, the bracket plate 210 is illustrated in FIG. 7 as having a rectangular shape elongated in the longitudinal direction X, but the technical concept is not limited thereto. The bracket plate 210 may have various shapes and may not need to be thin. However, for convenience of description, it will be described as having a rectangular thin plate shape elongated in the longitudinal direction.

The bracket module 200 may have different components coupled to the inner side 211 and the outer side 212 with respect to the bracket plate 210.

When the side of the bracket plate 210 facing the electrical compartment 53 is referred to as the inner side 211, the inner side 211 of the bracket plate 210 may include the support portion 211b to be in contact with the outer surface 52 of the electrical compartment plate 50 and the cover portion 211a corresponding to the bracket opening (300 in FIG. 6) formed in the electrical compartment plate 50 as described above. Since the cover portion 211a corresponds to the bracket opening (300 in FIG. 6), the shape of the cover portion 211a may match the shape of the bracket opening (300 in FIG. 6).

The bracket module 200 may include the fastening member 400 on one side. The fastening member 400 may be inserted into an electrical compartment fastening hole 54 (FIG. 6) formed in the electrical compartment plate 50, thereby coupling the bracket plate 210 to the electrical compartment plate 50.

The fastening member 400 may be a screw, rivet, or the like. However, it is not limited thereto, and the fastening member 400 may include any device capable of coupling the bracket plate 210 to the electrical compartment plate 50.

The bracket module 200 may include the locking member 220 on the other side. The locking member 220 may be locked with one side of the electrical compartment plate 50 to prevent the bracket module 200 from being separated while being coupled to the bracket plate 210.

The bracket module 200 may include the fastening members 400 on both sides for stable coupling. However, when the fastening members 400 are included on both sides, more time is used to fasten the fastening members 400 than in a configuration including the fastening member 400 on only one side. However, when the bracket module 200 includes the fastening member 400 on only one side and uses the locking member 220 on the other side, the assembly time may be reduced because it takes less time to seat the locking member 220 on the inner surface 51 of the electrical compartment plate 50 than fastening the fastening member 400.

The locking member 220 may be formed integrally with the bracket plate 210. The locking member 220 may be formed to extend from one side of the bracket plate 210. As the locking member 220 is formed integrally with the bracket plate 210, the production process of the bracket module 200 may be further simplified.

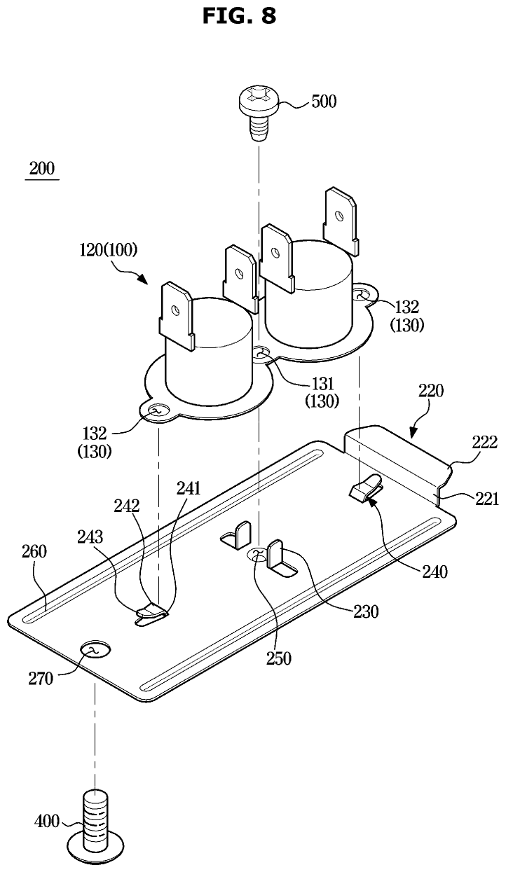

The shape that the fastening member 400 may have will be described below with reference to FIG. 8.

The bracket module 200 may include the electrical component 100. The electrical component 100 may be a sensor 120. More specifically, the electrical component 100 may be a thermal cut off (TCO) sensor 120 that detects the temperature and blocks the flow of current when the temperature exceeds a certain temperature. However, the disclosure merely describes an example, and the electrical component 100 is not limited thereto. Hereinafter, for convenience of description, it is assumed that the electrical component 100 is a sensor 120.

The sensor 120 may be coupled to the bracket plate 210. Specifically, the sensor 120 may be coupled to the inner side 211 of the bracket plate 210. Since the inner side 211 of the bracket plate 210 is the side facing the electrical compartment 53, when the bracket plate 210 is coupled to the electrical compartment plate 50, the sensor 120 may be located in the electrical compartment 53. The sensor 120 may be connected to other electrical components 100 to receive power or interact with the other electrical components 100 to perform the function. This may be achieved smoothly when the sensor 120 is located in the electrical compartment 53, and thus the sensor 120 may be located on the inner side 211 of the bracket plate 210 such that the sensor 120 may more smoothly perform the function.

More specifically, the sensor 120 may be located on the cover portion 211a on the inner side 211 of the bracket plate 210. The bracket opening 300 may be formed with a size that allows the electrical component 100 to pass therethrough, and when the sensor 120 is located on the cover portion 211a, the separation of the bracket module 200 from the electrical compartment plate 50 may be facilitated.

The bracket module 200 may include an electrical component fixing member 500 to fix the sensor 120 to the bracket plate 210. The electrical component fixing member 500 may be provided as a screw, rivet, and the like. However, it is not limited thereto and the electrical component fixing member 500 may be any device that may be used to fix the sensor 120 to the bracket plate 210.

The bracket module 200 may include a guide member 230 such that the electrical component fixing member 500 may be easily coupled to the coupling position on the bracket plate 210 in a process of coupling the electrical component fixing member 500 to the sensor 120 and the bracket plate 21. The guide member 230 may be formed adjacent to a position in which the electrical component fixing member 500 is to be coupled. The guide member 230 may be formed to protrude in the direction in which the electrical component fixing member 500 is to be coupled.

With the positional guide from the end tip in the protruding direction of the guide member 230 to the point at which the electrical component fixing member 500 is inserted, the electrical component fixing member 500 may be accurately coupled to the coupling position.

The guide member 230 may be formed integrally with the bracket plate 210. By the guide member 230 being integrally formed, the production process may be shortened. The guide member 230 may be formed in a portion of the bracket plate 210 that has been cut and bent. This will be described below with reference to FIG. 8.

The sensor 120 included in the bracket module 200 may be in plural. More specifically, the bracket module 200 may include two sensors 120. The electrical component fixing member 500 may be located in a portion in which the two sensors 120 overlap. Since such a configuration may prevent a situation in which the electrical component fixing members 500 are located to correspond with each sensor and thus it takes more time to fasten each electrical component fixing member 500, the fastening may require less time by using a single electrical component fixing member 500 with less time.

The electrical component fixing member 500 may be fastened on one side of the sensor 120. Since the electrical component fixing member 500 may be located only on one side of the sensor 120, a member for fixing the sensor 120 may also be needed on the other side. In this case, when the electrical component fixing member 500 is used on the other side, it takes a long time to fasten the electrical component fixing members 500. Therefore, an electrical component fitting member 240 may be used on the other side of the sensor 120 such that the sensor 120 is coupled to the bracket plate 210.

In other words, the bracket module 200 may further include the electrical component fitting member 240 to couple the sensor 120 to the bracket plate 210. The sensor 120 may be coupled to the bracket plate 210 by the electrical component fitting protrusion and the electrical component fixing member 500.

The bracket module 200 may include a reinforcing protrusion 260 to increase the strength of the bracket plate 210. The bracket plate 210 may have a shape of a thin plate. Therefore, when the bracket plate 210 is formed of a material having bending properties, the bracket plate 210 may be easily bent. When the bracket plate 210 is easily bent, the sensor 120 or the electrical component 100 coupled thereto may be separated from the bracket plate 210. Furthermore, when separating the bracket module 200 from the electrical compartment plate 50, it may be difficult to stably separate the bracket module 200. In order to prevent such a constraint, the bracket plate 210 needs to be strengthened.

Methods of increasing the strength of the bracket plate 210 may include increasing the thickness the bracket plate 210. However, the approach requires a lot of material to manufacture the bracket plate 210, which may increase the unit price of the product. In addition, when other components included in the bracket module 200 are formed integrally with the bracket plate 210, there is an increasing difficulty in producing such components.

When a reinforcing protrusion 260 protruding from the outer surface 52 or the inner surface 51 of the bracket plate 210 is formed on one or both sides of the bracket plate 210 while maintaining the thickness of the bracket plate 210, the strength of the bracket plate 210 may be increased without increasing the thickness of the bracket plate 210.

The reinforcing protrusion 260 may be formed to extend in the longitudinal direction of the bracket plate 210. Since there is a need to strengthen the bracket plate 210 as a whole, it is appropriate that the reinforcing protrusion 260 is formed along the longitudinal direction rather than the width direction in terms of increasing the strength of the bracket plate 210.

In addition, it is appropriate that the bracket plate 210 is coupled in close contact with the electrical compartment plate 50. When the cooking appliance 1 is an OTR, oil vapor formed by food cooked on the lower side of the cooking appliance 1 may be drawn into the cooking appliance 1 through the circulating air intake port (14 in FIG. 3) of the cooking appliance 1. Such an oil vapor may pass through the vent fan (110 in FIG. 3) and then through a passage separated from the electrical compartment 53, existing through the circulating air exhaust port (12 in FIG. 3). In this case, the oil vapor passes by the outer surface 52 of the electrical compartment plate 50, and when there is a gap between the bracket plate 210 and the electrical compartment plate 50, the oil vapor may enter the electrical compartment 53 through the gap. The electrical component 100 may break down due to the oil vapor entering the electrical compartment 53, which may lead to a fire. Therefore, it is appropriate that the bracket plate 210 is coupled in close contact with the electrical compartment plate 50 such that no gap is generated.

In order for the bracket plate 210 to be coupled in close contact with the electrical compartment plate 50, it may be appropriate that the electrical component 100, the guide member 230, the electrical component fitting member 240, and the like, which have a protruding shape, are located on the cover portion 211a of the bracket plate 210 that may not be in contact with the electrical compartment plate 50.

Similarly, it may be appropriate that the reinforcing protrusion 260 is also located on the cover portion 211a of the bracket plate 210. When there is a limit on the area of the cover portion 211a of the bracket plate 210, the reinforcing protrusion 260 may be located on the side in which the support portion 211b is located. Even in this case, it is required to prevent a gap between the bracket plate 210 and the electrical compartment plate 50, and thus it is appropriate that the reinforcing protrusion 260 is formed to protrude to the outside 212 of the bracket plate 210.

FIG. 8 is an exploded perspective view illustrating a state in which components of the bracket module 200 shown in FIG. 7 are disassembled.

As seen above, the bracket module 200 may include the fastening member 400.

Referring to FIG. 8, the fastening member 400 may pass through a plate fastening hole 270, which is a through hole formed on the bracket plate 210, to be inserted and coupled to the electrical compartment fastening hole (54 in FIG. 6) on the electrical compartment plate 50. Through the coupling, the bracket plate 210 may be coupled to the electrical compartment plate 50.

The direction in which the fastening member 400 is fastened to the bracket plate 210 may be a direction from the outer side 212 to the inner side 211 of the bracket plate 210. Since the outer side 212 of the bracket plate 210 is a part exposed to the outside when the housing plate (13 in FIG. 2) is removed from the outer housing (10 in FIG. 2), the end tip of the fastening member 400 may be easily visible from the outside. In particular, the fastening member 400 may be a screw, and when the fastening member 400 is fastened in the direction, the screw head, into which a driver or the like is inserted may be easily exposed to the outside. Therefore, the fastening member may be fastened in the direction such that the fastening member 400 may be easily separated from the bracket plate 210 from the outside of the cooking appliance 1.

The bracket module 200 may include the locking member 220. The locking member 220 may be formed integrally with the bracket plate 210. The locking member 220 may include a locking connection portion 221 that is bent and extended from one side of the bracket plate 210. The length by which the locking connection portion 221 extends may be equal to the height of the boundary of the bracket opening (300 in FIG. 5) as described above. Due to the length, when the bracket plate 210 is coupled to the electrical compartment plate 50, the step difference between the outer surface 52 of the electrical compartment plate 50 and the outer side 212 of the bracket plate 210 may be reduced.

The locking member 220 may include a locking support portion 222 that is bent and extended from an end tip of the locking connection portion 221. The locking support portion 222 may be inserted inwardly into the electrical compartment 53 such that when the bracket plate 210 is about to be separated from the electrical compartment plate 50, the locking support portion 222 may be supported on the inner surface 51 of the electrical compartment plate 50 to prevent the bracket plate 210 from being separated from the electrical compartment plate 50.

The support portion 211b provided on the inner side 211 of the bracket plate 210 described above may be supported on the outer surface 52 of the electrical compartment plate 50 when the bracket plate 210 is coupled to the electrical compartment plate 50 to prevent the bracket plate 210 from being inserted into the electrical compartment 53. Similarly, the locking member 220 described herein may be supported on the inner surface 51 of the electrical compartment plate 50 to prevent the bracket plate 210 from being separated from the electrical compartment plate 50.

When attempting to separate the electrical component 100 to the outside of the electrical compartment 53, the locking member 220 needs to pass through the bracket opening (300 in FIG. 6), and when attempting to locate the electrical component 100 back into the electrical compartment 53, the locking member 220 may need to pass through the bracket opening (300 in FIG. 6) again. Therefore, the width of the locking member 220 may be smaller than the width of the bracket opening 300.

Specifically, in order that the bracket module 200 is separable to the outside of the electrical compartment 53, the width of the locking member 220 measured in a direction perpendicular to the extending direction thereof may be smaller than the width of the bracket opening (300 in FIG. 6) measured in the same direction.

In addition, the locking support portion 222 forming the end portion of the locking member 220 may have a tapered shape of which the width becomes narrower toward the end tip. By having such a shape, it may become easier for the locking member 220 to pass through the bracket opening 300.

The bracket module 200 may include the electrical component fixing member 500 that couples the electrical component 100 to the bracket plate 210. To allow the electrical component fixing member 500 to pass therethrough, the electrical component 100 may include an electrical component fixing hole 130 on a side that is to be coupled to the bracket plate 210. The electrical compartment plate 50 may include a plate fixing hole 250 formed at a position corresponding to the electrical component fixing hole 130. The electrical component fixing member 500 may couple the electrical component fixing hole 130 and the plate fixing hole by passing through the electrical component fixing hole 130 and the plate fixing hole 250 to couple the electrical component 100 and the bracket plate 210.

In order to facilitate accurate insertion of the electrical component fixing member 500 into the plate fixing hole 250, the guide member 230 may be provided. The guide member 230 may be formed integrally with the bracket plate 210. Specifically, the guide member 230 may be formed in a portion of the bracket plate 210 that has been cut and extended with a bent. Since the guide member 230 is to allow the electrical component fixing member 500 to be more easily positioned in the plate fixing hole 250, the guide member 230 may be formed in a portion of the bracket plate 210 adjacent to the plate fixing hole 250 that has been cut and extended with a bent.

The direction in which the electrical component fixing member 500 is coupled to the bracket plate 210 may be a direction from the inner side 211 to the outer side 212 of the bracket plate 210. Since the coupling position of the electrical component fixing member 500 may be guided by the guide member 230, the electrical component fixing member 500 may need to be coupled on the inner side 211 of the bracket plate 210, which is a side to which the guide member 230 protrudes, such that the coupling position of the electrical component fixing member 500 may be guided. In addition, since a user who desires to replace the electrical component 100 may perform the task by placing the outer side 212 of the bracket plate 210 on the palm of his hand while keeping his or her gaze toward the inner side 211 of the bracket plate 210, the task may become easier when the end portion of the electrical component fixing member 500 is located on the inner side 211 of the bracket plate 210, at which the gaze is pointed.

Since the electrical component fixing member 500 may be located on one side of the electrical component 100, in order to more effectively fix the electrical component 100, it is appropriate to have a different structure for fixing the electrical component 100 on the other side. Accordingly, the electrical component fitting member 240 coupled to the other side of the electrical component 100 may be provided. The electrical component fixing hole 130 into which the electrical component fixing member 500 is inserted may be referred to as a first electrical component fixing hole 131. The electrical component fixing hole 130 into which the electrical component fitting member 240 coupled to the other side of the electrical component 100 is inserted may be referred to as a second electrical component fixing hole 132. In other words, the electrical component fitting member 240 may be inserted into the second electrical component fixing hole 132.

The electrical component fitting member 240 may be formed integrally with the bracket plate 210. The electrical component fitting member 240 may include a fitting connection portion 241 formed in a portion of the bracket plate 210 that has been cut and extended with a bent. Since the fitting connection portion 241 may extend in the direction in which the electrical component 100 is to be coupled to the bracket plate 210, the fitting connection portion 241 may be accommodated and positioned in the second electrical component fixing hole 132.

The electrical component fitting member 240 may include a fitting support portion 242 that is bent and extended from an end tip of the fitting connection portion 241. The fitting support portion 242 may extend across the direction in which the electrical component 100 is to be coupled to the bracket plate 210. Therefore, when the electrical component 100 is about to be separated from the bracket plate 210 while the fitting connection portion 241 is inserted into the second electrical component fixing hole 132, the electrical component 100 may be caught with the fitting support portion 242 and thus the separation may be prevented.

The electrical component fitting member 240 may include a fitting accommodating portion 243 that is bent and extended from the end tip of the fitting support portion 242. The fitting accommodating portion 243 may be bent in a direction opposite to the direction in which the electrical component fixing member 500 is to be coupled to the bracket plate 210. As a result, a gap at an entrance portion between the bracket plate 210 and the electrical component fitting member may increase, which makes it easier to accommodate the electrical component fitting member 240 inside of the second electrical component fixing hole 132.

Since two electrical components 100 may be provided, the first electrical component fixing holes 131 of the two electrical components 100 may be aligned with each other and coupled with a single electrical component fixing member 500, thereby coupling the electrical components 100 to the bracket plate 210. In addition, the second electrical component fixing hole 132 of each of the electrical components 100 may accommodate the electrical component fitting member 240 formed to extend from the bracket plate 210, thereby fixing the electrical components 100. With such a structure, only a single electrical component fixing member 500 may be used such that the fastening time of the electrical component fixing members 500 may be reduced.

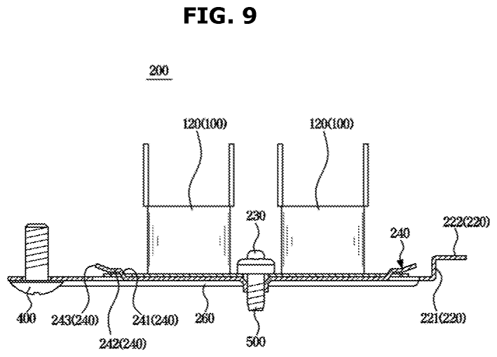

FIG. 9 is a cross-sectional view taken along BB′ of the bracket module 200 shown in FIG. 7.

Referring to FIG. 9, the electrical component 100 may be in a state of being coupled to the bracket plate 210.

The locking connection portion 221 of the locking member 220 may be bent vertically and extended toward the electrical compartment 53. By the locking connection portion 221 extended vertically, a gap that occurs with the electrical compartment plate 50 may be further reduced.

The fitting connection portion 241 of the electrical component fitting member 240 may be bent at a non-vertical angle and extended toward the electrical compartment 53. This is because the electrical component fitting member 240 may not need to be inserted in the vertical direction toward the electrical compartment 53 when it is inserted into the second electrical component fixing hole 132 since the electrical component fitting member 240 may include the fitting support portion 242 or the fitting accommodation portion 243 extending in the horizontal direction.

The fitting accommodation portion 243 of the electrical component fitting member 240 may be bent upward. Accordingly, it can be seen that the gap between the fitting member and the bracket plate 210 becomes larger as shown in FIG. 9.

The reinforcing protrusion 260 may protrude toward the lower side of the bracket plate 210 as shown in FIG. 9.

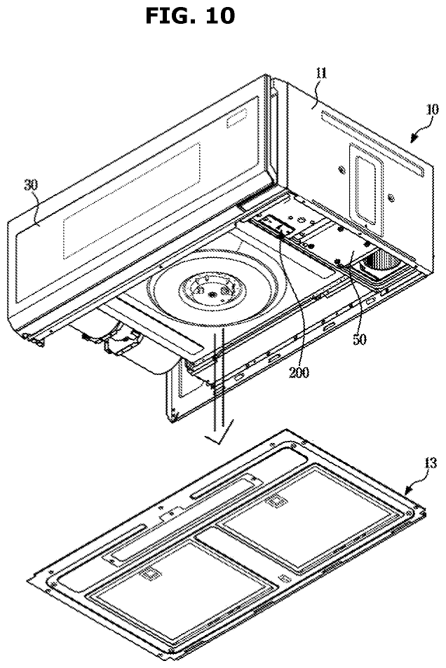

FIGS. 10 to 13 are views illustrating a service of replacing the electrical component 100 of the cooking appliance 1 according to the disclosure as an example.

FIG. 10 is a perspective view illustrating a process of the housing plate 13 being separated from the cooking appliance 1 of FIG. 1.

Referring to FIG. 10, the housing plate 13 provided on the lower side of the cooking appliance 1 may be separated. As the housing plate 13 is separated, the bracket module 200 coupled to the electrical compartment plate 50 is visible.

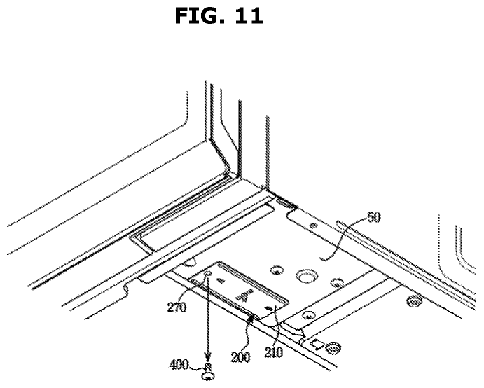

FIG. 11 is an enlarged perspective view illustrating a process of the fastening member 400 being separated from the bracket module 200 of the cooking appliance 1 shown in FIG. 10.

Referring to FIG. 11, the fastening member 400 fastened to the bracket plate 210 may be separated using a tool, such as a driver.

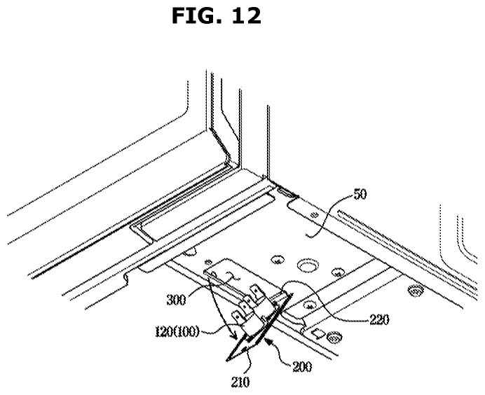

FIG. 12 is an enlarged perspective view illustrating a process in which the bracket module 200 of the cooking appliance 1 shown in FIG. 11 is rotated and separated from the electrical compartment plate 50.

Referring to FIG. 12, the bracket plate 210 on the side from which the fastening member 400 has been removed may first be separated from the electrical compartment plate 50. This is because there is a difficulty in separating both sides from the electrical compartment plate 50 at the same time due to the locking member 220 on the other side of the bracket plate 210.

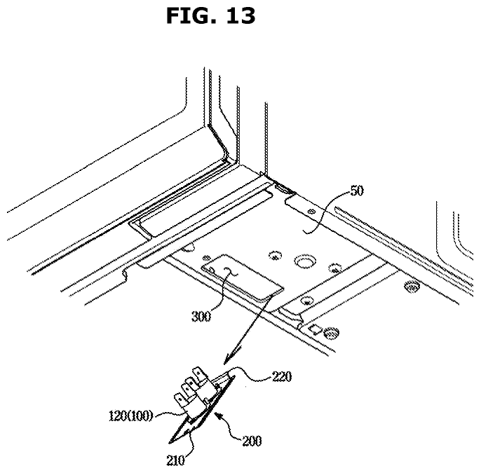

FIG. 13 is an enlarged perspective view illustrating a state in which the bracket module 200 of the cooking appliance 1 shown in FIG. 12 has been separated from the electrical compartment plate 50.

Referring to FIG. 13, the bracket plate 210 may be tilted to a side from which the fastening member 400 has been separated such that the bracket plate 210 may be separated from the electrical compartment plate 50.

Accordingly, the bracket module 200 may be separated to the outside and the electrical component 100 may be provided to be replaceable.

Reassembling the bracket module 200 to return to the original state of the cooking appliance 1 is achieved by reversing the processes described above with reference to FIGS. 10 to 13.

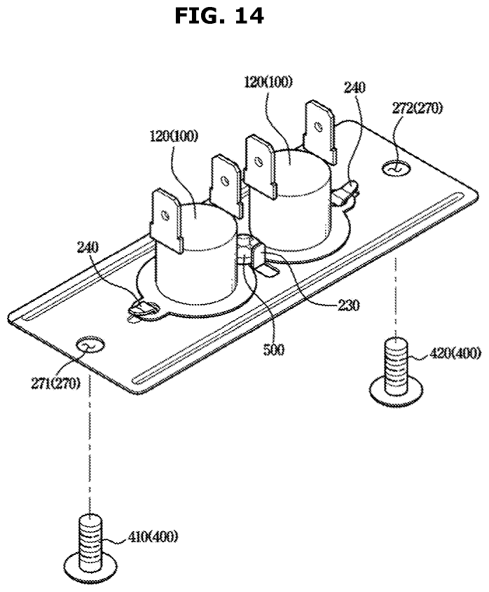

FIG. 14 is an enlarged perspective view illustrating a bracket module 200 of a cooking appliance 1 according to another embodiment.

Referring to FIG. 14, a bracket plate 210 may have fastening members 400 coupled to both sides thereof. The fastening members 400 fastened to the both sides of the bracket plate 210 may be referred to as a first fastening member 410 and a second fastening member 420, respectively. Plate fastening holes 270 into which the fastening members 400 are inserted may be referred to as a first plate fastening hole 271 and a second plate fastening hole 272, respectively.

With such a structure, the bracket module 200 may be provided with a stronger coupling with the electrical compartment plate 50 when compared to the above described embodiment.

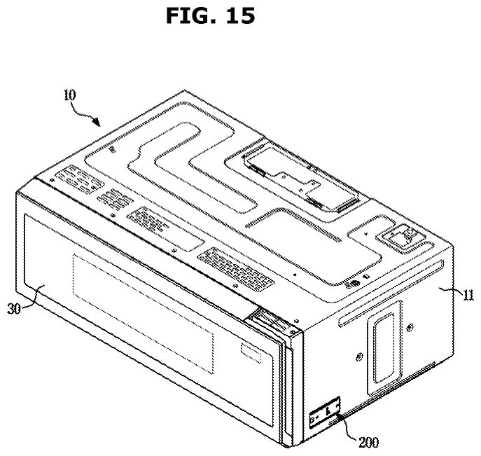

FIG. 15 is a perspective view illustrating a cooking appliance 1 according to another embodiment.

Referring to FIG. 15, a bracket module 200 may be coupled to an outer housing cover 11.

Such a structure may prevent a situation in which the bracket module 200 is located on the lower side of the cooking appliance 1 and easily separated and thus the electrical component 100 coupled to the bracket module 200 easily falls to the ground and broken, and may omit a process of separating the housing plate 13 from the cooking appliance 1 in the process of replacing the electrical component 100, thereby providing faster service.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A cooking appliance comprising:
an outer housing;
an inner housing disposed inside the outer housing;
an electrical compartment formed in the inner housing;
an electrical compartment plate arranged between the outer housing and the inner housing to divide the electrical compartment, the electrical compartment plate including a bracket opening on one side thereof; and
a bracket module separably coupled to the electrical compartment plate, the bracket module including a bracket plate configured to cover the bracket opening in response to the bracket module being coupled to the electrical compartment plate; and
an electrical component coupled to one side of the bracket plate, and to be located inside of the electrical compartment through the bracket opening while the bracket module is coupled to the electrical compartment plate,
wherein the bracket module is separated from the electrical compartment plate such that the electrical component is configured to be separable to an outside of the electrical compartment.

2. The cooking appliance of claim 1, wherein the bracket opening having a size that the electrical component is separable to the outside of the electrical compartment through the bracket opening in response to the bracket module being separated from the electrical compartment plate.

3. The cooking appliance of claim 1, wherein the electrical compartment plate includes an outer surface facing in a direction opposite to a direction toward the electrical compartment,
the bracket plate includes an inner side facing the electrical compartment and an outer side facing opposite to the inner side, and the inner side of the bracket plate includes:
a cover portion corresponding to the bracket opening; and
a support portion formed along a circumference of the bracket opening and supported by the outer surface of the electrical compartment plate.

4. The cooking appliance of claim 3, wherein the electrical component is coupled to the cover portion of the bracket plate.

5. The cooking appliance of claim 1, wherein the bracket module further includes a fastening member coupled to one side of the bracket plate in a direction from an outer side to an inner side of the bracket plate.

6. The cooking appliance of claim 1, wherein the bracket module further comprises a locking member formed to extend from an other side of the bracket plate, and configured to be inserted into the electrical compartment through the bracket opening and supported on an inner surface of the electrical compartment plate while the bracket module is coupled to the electrical compartment plate.

7. The cooking appliance of claim 6, wherein the locking member has a width smaller than a width of the bracket opening such that the bracket module is configured to be separable to the outside of the electrical compartment.

8. The cooking appliance of claim 6, wherein the locking member includes:
a locking connection portion bent at the other side of the bracket plate in a direction in which the bracket module is coupled to the bracket opening, and extending by a height of a boundary of the bracket opening such that the bracket plate is coupled in close contact with the electrical compartment plate; and
a locking support portion bent at an end tip of the locking connection portion and extending in a longitudinal direction of the bracket module.

9. The cooking appliance of claim 1, wherein the bracket module includes a reinforcing protrusion formed in a longitudinal direction of the bracket plate to reinforce the bracket plate, and the reinforcing protrusion is formed on an outer side of the bracket plate such that the bracket plate is coupled in close contact with the inner housing.

10. The cooking appliance of claim 1, wherein the electrical component includes an electrical component fixing hole formed on a surface coupled to the bracket plate,
the bracket plate includes a plate fixing hole formed at a position corresponding to the electrical component fixing hole, and
the bracket module includes an electrical component fixing member coupled at a position corresponding to the electrical component fixing hole and the plate fixing hole on an inner side of the bracket plate to couple the electrical component to the bracket plate.

11. The cooking appliance of claim 10, wherein the bracket module includes a guide member located adjacent to the plate fixing hole and protruding from the inner side of the bracket plate to guide fastening of the electrical component fixing member to the plate fixing hole.

12. The cooking appliance of claim 10, wherein the electrical component fixing hole is a first electrical component fixing hole,
the electrical component includes a second electrical component fixing hole, formed at a side opposite the first electrical component fixing hole, on a surface coupled to the bracket plate, and
the bracket module includes an electrical component fitting member at a position corresponding to the second electrical component fixing hole on the bracket plate, the electrical component fitting member protruding toward the electrical component to fix the electrical component to the bracket plate.

13. The cooking appliance of claim 1, wherein the electrical component includes a thermal cut off (TCO) sensor configured to detect temperature and block flow of current when the temperature exceeds a preset temperature.

14. The cooking appliance of claim 1, wherein the outer housing includes a housing plate separably coupled to the bracket plate to cover the electrical compartment plate, and
the bracket module is accessible as the housing plate is separated from the electrical compartment plate.

15. The cooking appliance of claim 14, wherein
the housing plate forms a bottom of the cooking appliance and includes an air inlet,
the bracket module is separably coupled to a lower surface of a front side of the electrical compartment plate, and
a circulating air intake port is formed on a rear side of the electrical compartment plate to intake external air through the air inlet.
